(19) United States
(12) Patent Application Publication
(10) Pub. No.: US 2009/0266396 A1
(43) Pub. Date: Oct. 29, 2009

(54) Polycrystalline Silicon Substrate, Method for Producing Same, Polycrystalline Silicon Ingot, Photoelectric Converter and Photoelectric Conversion Module

(75) Inventors: Koichiro Niira, Shiga (JP); Shigeru Gotoh, Shiga (JP)

Correspondence Address: HOGAN & HARTSON L.L.P., 1999 AVENUE OF THE STARS, SUITE 1400, LOS ANGELES, CA, 90067, US

(73) Assignee: KYOCERA CORPORATION, Kyoto-shi, Kyoto (JP)

(21) Appl. No.: 11/910,217

(22) PCT Filed: Mar. 27, 2006
(86) PCT No.: PCT/JP2006/306178

§ 371 Date: Sep. 28, 2007

(30) Foreign Application Priority Data
Mar. 29, 2005 (JP) 2005-095709

(51) Int. Cl. H01L 31/042; H01L 29/04; H01L 31/0368; B29C 39/42

(52) U.S. Cl. 136/244; 257/49; 136/258; 264/82; 257/E29.003

(57) ABSTRACT

Disclosed is a polycrystalline silicon substrate having a region wherein concentrations of impurities contained therein satisfy the following relations: [Oi]≧2E17 [atoms/cm³] (under condition 1a and [C]≦1E17 [atoms/cm³] (Condition 2)) where [Oi] is the interstitial oxygen concentration determined by Fourier transform infrared spectroscopy and [C] is the total carbon concentration determined by secondary ion mass spectrometry. This polycrystalline silicon substrate has high strength adequate for a thinner substrate, while having good quality and high photoelectric conversion efficiency. Such a polycrystalline silicon substrate enables to produce a resource-saving, highly efficient polycrystalline silicon solar cell at low cost.

### TECHNICAL FIELD

The present invention relates to a polycrystalline silicon substrate with high photoelectric conversion efficiency and high strength and a method for producing same, and a polycrystalline silicon ingot. This silicon substrate is used for photoelectric conversion elements and photoelectric conversion modules including photoelectric conversion elements arrayed therein.

In this specification, the notation “aEn” represents a×10ⁿ.

### BACKGROUND ART

The current, mainstream solar cell products are bulk crystalline Si solar cells using crystalline Si substrates. In particular, those using polycrystalline Si substrates are produced in the greatest scale and the production amount thereof is expected to continue growing because high efficiency and low cost can both be achieved at the same time with this type of substrates.

The patent document 1 listed below discloses the results of investigating conditions for producing polycrystalline silicon ingot for obtaining high energy conversion efficiency, where the mutual relationships in concentration among light atom impurities including C, O, B, P and the like are taken into consideration in producing a polycrystalline silicon ingot from which polycrystalline Si substrates are sliced out.

The patent document 2 listed below describes purification processes for removing C and O, respectively, in a phase of molten silicon in a process of manufacturing silicon for use in solar cells.

The patent document 3 listed below describes purification processes for removing C and O, respectively, in a phase of molten silicon in a process of manufacturing a silicon ingot for use in solar cells.

The patent document 4 listed below discloses a process through which the ratio between O and C contents can be optimized in manufacturing a silicon ingot for use in solar cells.

Patent document 1: Japanese Unexamined Patent Publication No. 10-251010
Patent document 2: Japanese Unexamined Patent Publication No. 10-265213
Patent document 3: Japanese Unexamined Patent Publication No.
Patent document 4: Japanese Unexamined Patent Publication No.

### DISCLOSURE OF THE INVENTION

### Problems to be Solved by the Invention

As described above, the currently mainstream solar cell is bulk polycrystalline Si solar cell (hereinafter also simply referred to as “polycrystalline Si solar cell”) using polycrystalline Si substrate. In order to achieve lower cost and more resource-saving solar cells, thinning polycrystalline Si substrates is indispensable.

That is, by reducing the thickness of each substrate, the number of substrates per polycrystalline Si ingot is increased, so that more polycrystalline Si substrates can be manufactured with less Si material.

While the thickness of the substrate at present is, for example, on the order of 250-300 μm before cell fabrication (210-260 μm after cell fabrication), it is desired that the thickness of the substrate is 200-250 μm, in future, 200 μm or less, and more desirably, 150 μm or less.

However, as the substrate becomes thinner, it tends to have lower strength and higher crack/fracture rate.

For this reason, providing the substrate with both high strength and high quality has been an object to be achieved.

Conventionally, due to inadequate control and administration of concentrations of light atoms such as O, C, N and the like in polycrystalline Si substrates, achieving high strength and high quality at the same time has not been realized.

While increasing interstitial oxide concentration [Oi] is effective to enhance the substrate strength, it has been difficult to maintain and control the [Oi] at a required value throughout the height of the ingot by conventional polycrystalline silicon casting techniques. This is because oxygen evaporates as SiO₂ gas at a high rate from the surface of molten silicon during the casting, and the oxygen concentration in the molten liquid sharply decreases as solidification proceeds.

The interstitial oxygen concentration [Oi] here indicates proportion of oxygen located between lattice points of silicon crystal.

Further, carbon itself causes defects to generate in silicon, degrading the substrate quality. Furthermore, it is known that carbon also acts as a nucleus for oxygen precipitation. It has been known that the precipitated oxygen forms a dislocation loop to act as a dislocation proliferating source causing degradation of substrate quality.

Therefore, in order to maintain and control [Oi] to be at a higher concentration than conventional cases and to adequately suppress oxygen precipitation, carbon concentration [C] needs to be reduced sufficiently.

Since the conventional polycrystalline Si casting techniques fail to sufficiently reduce carbon contamination in molten silicon caused by CO gas (a phenomenon of C fusing into the molten liquid due to a chemical reaction between CO gas and molten silicon), when oxygen concentration is increased, the amount of oxygen precipitation increases in proportion thereto, inevitably leading to degradation in substrate quality and substrate strength.

It is an object of the present invention to provide a polycrystalline Si substrate having high strength and high quality while addressing to thinner substrates, a production method thereof and a polycrystalline silicon ingot.

It is another object of the present invention to provide a photoelectric conversion element and a photoelectric conversion module with high efficiency using the polycrystalline silicon substrate that can be realized at lower cost and with less resource.

### Means for Solving the Problems

A polycrystalline silicon substrate according to the present invention comprises a region which contains concentrations of impurities that satisfy the following relations: [Oi]≧2E17[atoms/cm³] (Condition 1a), and [C]≦1E17 [atoms/cm³] (Condition 2) where [Oi] [atoms/cm³] is an interstitial oxygen concentration determined by Fourier transform infrared spectroscopy and [C] [atoms/cm³] is a total carbon concentration determined by secondary ion mass spectrometry.

Further, a polycrystalline silicon substrate according to the present invention comprises a region which contains concentrations that satisfy, additionally to the foregoing Condition 2, the following relation:

[Oi]÷30×[N]≧2E17[atoms/cm³] (Condition 1b)

where [N] [atoms/cm³] is a total concentration of nitrogen determined by secondary ion mass spectrometry.

Since the polycrystalline silicon substrate satisfying the “foregoing conditions 1a and 2” or the polycrystalline silicon substrate satisfying the “foregoing conditions 1b and 2” has a large interstitial:oxygen concentration [Oi], it has a high strength adequate for a thinner substrate, and because of its low total carbon concentration [C], the substrate has high quality and high photoelectric conversion efficiency. A low cost, resource-saving polycrystalline silicon solar cell with high efficiency can thus be produced.

As for the total nitrogen concentration [N], a certain amount of nitrogen is naturally included in the ingot where a SiN mold releasing agent is applied to the inner wall surface of the mold. In the CZ technique, it is known that the dislocation fixation effect of [N] is about thirty times that of [Oi] (N is related to substrate quality in terms of the effect of suppressing proliferation of dislocations rather than to substrate strength). Further in polycrystalline silicon according to the present invention, it is basically possible to assume the function of [N] to be about thirty times that of [Oi].

The polycrystalline silicon substrate may be one that is sliced out from an ingot.

It is preferred that the foregoing “Condition 1a and Condition 2” or the foregoing “Condition 1b and Condition 2” are satisfied at least in a part of regions of the polycrystalline silicon substrate excluding a 1 cm wide peripheral edge portion of the substrate, or more preferably, the foregoing “Condition 1a and Condition 2” or the foregoing “Condition 1b and Condition 2” are satisfied in all of the regions excluding a 1 cm wide peripheral edge portion of the substrate.

The reason for excluding 1 cm wide peripheral edge portions of the substrate is that the substrate peripheral edge portions include a region solidified during an initial stage of solidification, and is affected by solid phase diffusion (thermal diffusion after solidification) of impurities from the inner wall of the mold, so that influences of factors other than the quality degrading factors as an object of the present invention are great in such a region. For this reason, it may be sometimes inappropriate to include such a region in the regions where advantageous effects of the present invention are expected to be exerted. Therefore, the substrate quality is evaluated on regions excluding 1 cm wide peripheral edge portions of the substrate so that the influences of factors other than the factors as an object of the present invention are almost negligible, by which the effects of the present invention are properly evaluated.

In addition, a polycrystalline silicon ingot for use in a photoelectric conversion element according to the present invention comprises an ingot including a region where concentrations of impurities contained therein satisfy the “Condition 1a and Condition 2” or the “Condition 1b and Condition 2”.

A method of producing a polycrystalline silicon substrate according to the present invention comprises the steps of: loading silicon into a crucible; substantially hermetically sealing the crucible inside a heating furnace; melting the silicon in the crucible; transferring the molten silicon into a mold and solidifying and cooling the silicon while supplying oxygen to the molten silicon liquid to obtain a polycrystalline silicon substrate.

Instead of or in addition to hermetically sealing the crucible, hermetically sealing the mold is also effective.

Moreover, the present invention is also applicable to an intra-mold melt and solidify method without using a crucible in which silicon is subjected to melting inside the mold followed by solidification and cooling.

By using these methods, the following effects can be obtained.

In conventional polycrystalline Si casting methods, due to the large proportion of the contact area of the furnace interior atmosphere to the amount of molten silicon, Co gas contamination is prone to occur. Therefore, (1) by melting silicon using a hermetically sealed crucible for melting and/or a hermetically sealed mold for solidification, molten silicon can be prevented from being in contact with Co gas present in the furnace during the casting, so that contamination of silicon by carbon can be minimized.

In addition, as described above, since oxygen evaporates as SiO gas at a high rate from the surface of the molten silicon during the casting to decrease the oxygen concentration in the molten liquid sharply as solidification proceeds, the oxygen concentration in the molten liquid is usually significantly lower than 1E18 [atoms/cm³] except during a short period of time immediately after melt is poured. For this reason, removal of carbon from the molten liquid by Co gas evaporation is hardly expected. Therefore, (2) by purposely supplying oxygen into the molten liquid during solidification, the oxygen concentration in the molten liquid can be controlled, so that also removal of carbon by Co gas evaporation can be also expected.

Combining the foregoing means (1) and (2) makes it possible to maintain [Oi] for enhancing substrate strength throughout the height of the ingot, and also to sufficiently reduce [C] that deteriorates substrate quality.

Moreover, improvement in cell efficiency can be realized at the same time. This is assumed to be because occurrences of dislocations are suppressed owing to the improved substrate strength.

Meanwhile, the aforementioned “substantially hermetically sealing the crucible inside the heating furnace” means that the crucible may be provided with an inert gas introducing port and a discharging port so that inert gas is not prevented from flowing inside the hermetically sealed crucible during the melting of silicon. This is because the purpose of hermetically sealing the crucible is to prevent CO gas from flowing into the crucible, and preventing inert gas flow is not intended.

Means to supply oxygen to the molten silicon liquid includes loading quartz into the molten silicon liquid. That is, an appropriate amount of oxygen is purposely supplied into the molten liquid by loading quartz powder or immersing quartz flakes in the molten liquid during solidification. Since this method is to supply oxygen in the solid state and not in the state of gas, Co generation due to a reaction between carbon material inside the furnace and gas including oxygen can be avoided. Further, in combination with the foregoing hermetically sealed mold, carbon contamination of the molten liquid can be avoided.

A photoelectric conversion element according to the present invention is a photoelectric conversion element using the aforementioned polycrystalline silicon substrate of the present invention. This photoelectric conversion element can be expected to be thinner and to have improved conversion efficiency as compared to conventional photoelectric conversion elements.

A photoelectric conversion module according to the present invention comprises a plurality of photoelectric conversion elements of the present invention that are arranged in series or in parallel being electrically connected, so that it can be realized as a low cost photoelectric conversion module with high conversion efficiency.

These and other advantages, features and effects of the present invention will be apparent from the following description of illustrative embodiments with reference to the accompanying drawings.

### BRIEF DESCRIPTION OF THE DRAWINGS

FIG. 1 is a cross-sectional view showing one example of the structure of a solar cell element 11 using a polycrystalline silicon substrate according to the present invention;

FIG. 2 is a top view showing one example of electrode configuration of the solar cell element 11 viewed from the light-entrance surface side;

FIG. 3 is a bottom view showing one example of electrode configuration of the solar cell element 11 viewed from the non-light-entrance surface side;

FIG. 4(a) is a diagram showing a state where silicon material has been loaded into a crucible in a process from initiation of melting silicon inside a crucible to transferring molten liquid to a mold;

FIG. 4(b) is a diagram showing a state where the silicon material is being melted inside the crucible by heating in a melting furnace in the process from initiation of melting silicon inside a crucible to transferring molten liquid to a mold;

FIG. 4(c) is a diagram showing a state where a dopant is added to the molten silicon in the process from initiation of melting silicon inside a crucible to transferring molten liquid to a mold;

FIG. 4(d) is a diagram showing a state where the molten silicon is poured into a mold in the process from initiation of melting silicon inside a crucible to transferring molten liquid to the mold;

FIG. 5 is a cross-sectional view showing the structure of a hermetically sealed crucible used in the production of a polycrystalline silicon substrate according to the present invention;

FIG. 6 is a diagram showing a state where molten silicon is being poured from an upper opening of a crucible;

FIG. 7 is a cross-sectional view showing the structure of a hermetically sealed mold used in the production of a polycrystalline silicon substrate according to the present invention;

FIG. 8 is a cross-sectional view showing the structure of a solar cell module; and

FIG. 9 is a top view showing this solar cell module viewed from the light-entrance side thereof.

### DESCRIPTION OF REFERENCE CHARACTERS

1 Surface collector electrode
   1a Bus bar electrode
   1b Finger electrode
3 Semiconductor region
4 Opposite conductivity-type region
5 P-type bulk region
6 Antireflective film
P⁺-type region
8 Back surface collector electrode
11 Solar cell element
12 Crucible body
13 Lid of crucible
14 Ar gas introduction port
15 Injection port
21 Mold body
22 Lid of mold
23 Inlet of Ar gas
24 Cooling plate
41 Wiring member
42 Transparent member
43 Back surface protecting member
44 Surface side filler
45 Back side filler
46 Output extracting wiring
47 Terminal box
48 Frame
H Heater/heat insulator

### BEST MODE FOR CARRYING OUT THE INVENTION

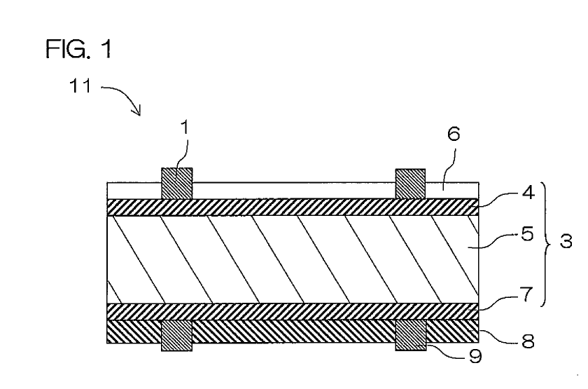

FIG. 1 is a cross-sectional view showing one example of the structure of a solar cell element 11 using a polycrystalline silicon substrate of the present invention.

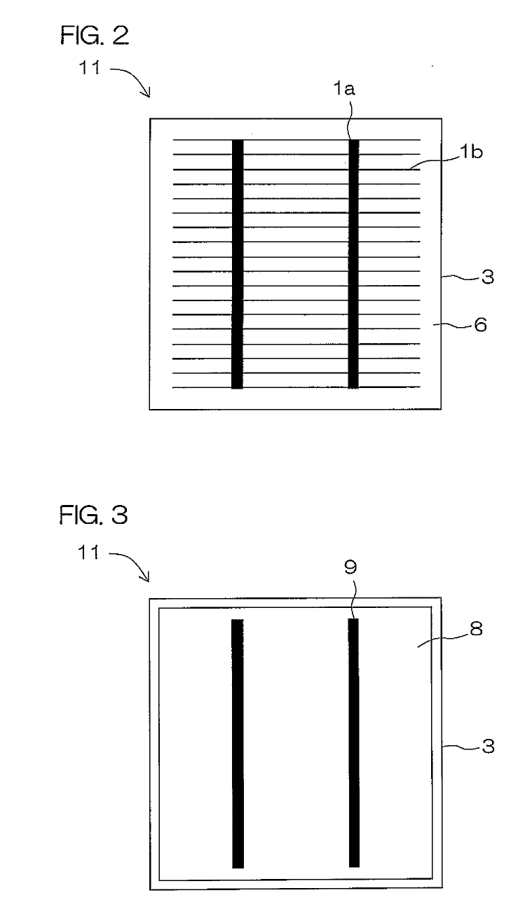

Further, FIGS. 2 and 3 illustrate one example of electrode configuration of the solar cell element 11, in which FIG. 2 is a top view seen from the light-entrance surface side, and FIG. 3 is a bottom view seen from the non-light-entrance surface side.

A brief description will be given of the structure of this solar cell element 11.

A p-type silicon substrate includes a p-type bulk region 5 as shown in FIG. 1. On a light-entrance surface side of the p-type silicon substrate, an opposite conductivity-type region 4 that is formed as n-type where P (phosphorus) atoms are diffused at a high concentration, and a pn junction is formed between the opposite conductivity-type region and the p-type bulk region. The thickness of this opposite conductivity-type region 4 is generally about 0.2 to 0.5 μm.

An antireflective film 6 including a silicon nitride film, silicon oxide film or the like is formed on the semiconductor on the light-entrance surface side. On the opposite side of the light-entrance surface, a p⁺-type region 7 is formed including a great amount of p-type semiconductor dopant such as aluminum. This p⁺-type region 7 is also called BSF (Back Surface Field) region and functions to reduce the ratio of recombination loss of photogenerated carriers upon their arrival at the back surface collector electrode 8. This improves photoelectric current density (Jsc). In addition, the density of minority carriers are reduced in this p⁺-type region 7, which works to reduce diode current (dark current) in this p⁺-type region 7 and the region in contact with the back surface collector electrode 8, so that open circuit voltage Voc is improved.

Surface collector electrodes 1 composed mainly of a metal material such as silver are provided on the light-entrance surface side. A back surface collector electrode 8 composed mainly of aluminum or the like is provided on the back surface side. In addition, back surface output electrodes 9 for collecting electric current from the back surface collector electrode 8 are also provided.

As shown in FIG. 2, the surface collector electrodes 1 generally includes finger electrodes 1b (branch electrodes) with small widths and bus bar electrodes 1a (trunk electrodes) with large widths to which at least one ends of the finger electrodes 1b are connected. In order to minimize loss of electric power at the surface collector electrodes 1, metal material is employed for the surface collector electrodes 1.

It is preferable to use Ag paste composed mainly of silver having a low resistivity as the metal material, which is generally applied by screen printing and baked to form electrodes.

When light enters from the side of the antireflective film 6, which is the light-entrance surface side of the solar cell element 11, the light is absorbed and photoelectrically converted at the semiconductor region 3 including the opposite conductivity-type region 4, bulk region 5 and p⁺-type region 7 to generate electron-positive hole pairs (electron carriers and positive hole carriers). These photo excited electron carriers and positive hole carriers (photogenerated carriers) generate photoelectromotive force between the generally linear-shaped surface collector electrodes 1 provided on the surface side of the solar cell element 11 and the back surface electrodes 8, 9 provided on the back surface side. Then the photogenerated carriers are collected by these electrodes to be directed to the output terminal. In addition, dark current as diode current flows in the opposite direction of the photoelectric current in accordance with the photoelectromotive force.

Now, a polycrystalline silicon ingot-casting method for obtaining a polycrystalline silicon substrate of the present invention is described.

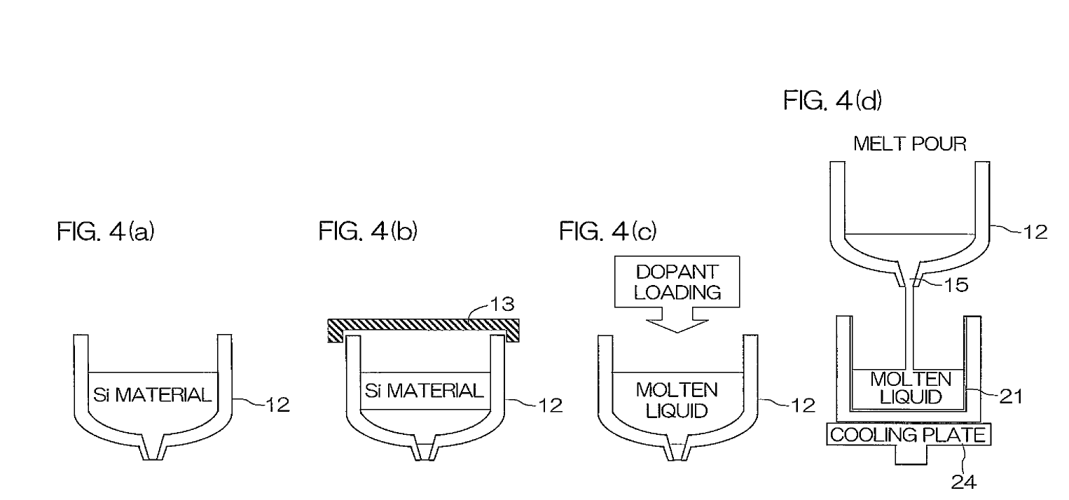

FIGS. 4(a)-4(d) are process drawings illustrating a process from initiation of melting silicon inside a crucible to transferring molten liquid to a mold.

First, a silicon material is prepared. While the silicon material is preferably a poly-silicon material with a low impurity concentration, it is also possible to use other kinds of silicon including off-grade silicon so-called “top” or “tail” generated during the manufacture of single crystal silicon ingot by the CZ method or residual silicon that remains in the crucible. However, in cases where the problem of impurity contamination arises due to the use of off-grade silicon or residual silicon, an appropriate amount of poly-silicon material is mixed thereto.

Hereinafter, a case where about 80 kg of Si material is prepared will be described by way of example.

The silicon material is loaded into a crucible. FIG. 4(a) illustrates a state where the silicon material has been loaded into the crucible. The crucible may be a quartz crucible generally used in the CZ method.

FIG. 4(b) illustrates a state where the silicon material is being melted in a melting furnace by heating. The furnace interior is kept in an Ar gas atmosphere which is controlled so that the Ar flow rate is in a range of about 10-100 L/min and the Ar gas pressure is in a range of about 1 kPa-100 kPa (atmospheric pressure).

In this embodiment, when a quartz crucible is used, oxygen concentration in the molten silicon in this melting step is on the order of 1E18-2E18 [atoms/cm³], which is so high as to approximate the saturation solubility. When the inner wall of the quartz crucible is coated with non-oxide material such as SiN, the oxygen concentration in the molten silicon becomes smaller than this value. When a SiN-based mold releasing agent is applied to the inner wall surface of the mold, nitrogen is mixed into the molten silicon. Since the dislocation fixation effect of [N] is assumed to be about thirty times that of [Oi] also in polycrystalline Si, this can be expected to have an effect alternative to the crystal strength enhancing effect of interstitial oxygen in Si crystal in solidification of the molten silicon.

Attention should be given in the step of melting silicon to carbon contamination of molten silicon by CO gas inside the furnace. As the carbon concentration in the molten silicon increases, the carbon concentration in the formed Si ingot also increases accordingly, which becomes a factor of deterioration of substrate quality (promotion of oxygen precipitation).

There are two factors for reducing this carbon contamination: (1) reduction of CO partial pressure and (2) shortening the melting time

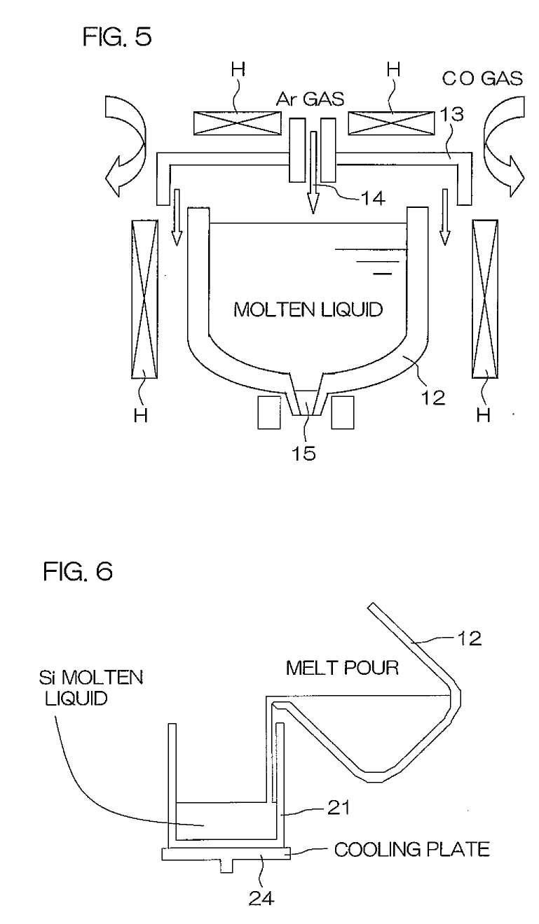

While the reduction of CO partial pressure set forth in (1) above can be realized to a certain extent, for example, by increasing rate of gas discharge from the interior of the furnace (i.e., increasing the Ar gas flow rate), in order to suppress carbon contamination to a minimum, using the hermetically sealed crucible (See FIGS. 4 (b) and 5) according to the present invention is very effective. This enables efficient reduction of carbon contamination to a minimum with a small amount of Ar gas flow without the need to increase the Ar gas flow rate.

It goes without saying that general conditions for reduction of Co gas partial pressure should be sufficiently satisfied as a precondition for obtaining the effect of reducing Co gas contamination using the hermetically sealed crucible. That is, it is important to take measures in a comprehensive way, including reduction of the amount of residual gas (absorbed gas) inside the furnace, reduction of the amount of air leakage into the furnace, reduction of CO gas generating reactions inside the furnace, increasing the discharge rate of the furnace interior gas, optimizing the Ar gas flow path inside the furnace, and optimizing the arrangement of carbon containing heater and heat insulator.

The sources of CO gas generation inside the furnace include the heater and heat insulator constructed with a carbon material, which react with oxygen including gases to generate CO gas. Specifically, this is described as follows:

C material+air leak components (O₂,H₂O)→CO⇑

C material+SiO→SiC (or Si)+CO⇑

The reaction in the latter formula is caused by a great amount of SiO gas generated during melting, which is an inevitable reaction in a melting process where a quartz crucible is used.

In order to suppress the reaction between the carbon material and oxygen including gas in the foregoing formula, there are cases where SiC coating over the surface of the carbon containing member is effective (T. Fukuda et al: J. Electrochem. Soc., vol. 141, No. 8, August 1994, p. 2216).

While increasing the discharge rate of the furnace interior gas mentioned above can be accomplished by increasing the capacity of the exhaust pump. However, since there is a limit in the pump exhaust capacity, decreasing the effective volume of the furnace interior (the volume of the region where furnace interior gas actually exists) as much as possible is effective in this case.

Here, gas stay time constant τ is defined by the following formula:

τ=furnace interior Ar gas mol number/Ar gas flow rate [mol/sec]

(where furnace interior Ar gas mol number∝furnace interior effective volume×furnace interior Ar gas density)

Using τ defined as an index, the degree of the gas discharge rate can be found out. The Ar gas density in the furnace is a quantity that can be determined using the state equation: PV=nkT, that is re-written to n/V=P/kT. Since estimating the actual furnace interior effective volume takes some effort, instead, τ is used as a relative index, which is determined using furnace interior design volume (volume of furnace interior space). Even so, the discussion hereafter will not be affected.

When this furnace interior design volume is used as the furnace interior volume, according to the previous experiences, the value of τ required for effectively reducing CO gas contamination is not more than 25 sec, and preferably not more than 15 sec. However, this condition can be more lenient when the hermetically sealed crucible is used.

In addition, the foregoing Ar gas flow path is also a very important designing element. Basically, the structure of the furnace interior is designed such that fresh Ar gas can be blown on the surface of molten silicon and the Ar gas flows in the form of a laminar flow (to prevent turbulent flow part from generating) in one direction without causing any component to flow backward so as to be guided to the discharge port. When it is formed as the hermetically sealed crucible, the purposes described here will be almost automatically achieved.

In addition, optimum conditions for the aforementioned arrangement of the carbon containing heater and heat insulator need to be determined taking the relationship between the location of the surface of the molten silicon and the Ar gas flow path into consideration. However, the purpose discussed here will be almost automatically achieved using the hermetically sealed crucible as shown in FIG. 5.

FIG. 5 is a cross-sectional view of a hermetically sealed crucible used in the present invention. This hermetically sealed crucible is constituted of a crucible body 12 and a detachable lid 13 of the crucible.

The lid 13 of the crucible is formed with an introduction port 14 for introducing Ar gas to flow inside the crucible. There is a clearance for allowing the Ar gas to exit the crucible between the crucible body 12 and the lid 13.

In addition, an openable/closable injection port 15 for injecting molten silicon into the mold is provided in a bottom portion of the crucible body 12.

The “H” represents a heater or a heat insulator including carbon material for heating the crucible.

Furthermore, a lid lifting/lowering mechanism (not shown) for attaching/detaching the lid 13 of the crucible may be provided inside the melting furnace. This is provided for detaching the lid 13 of the crucible for injecting dopant and attaching the lid 13 again after the injection of the dopant. However, arranging the lid 13 to be attachable/detachable is not an indispensable requisite. Instead of the attachable/detachable lid, a hole or mechanism allowing for injection of dopant may be provided in the crucible or the lid.

When silicon is melted using this hermetically sealed crucible, the effect of reducing the CO partial pressure inside the crucible can be obtained. Therefore, contact between the molten liquid and CO gas can be reduced without purposely increasing the Ar flow rate. Therefore, carbon contamination can be suppressed efficiently to a minimum with a small Ar flow rate.

Concerning shortening the melting time mentioned in (2) above, it is preferable for reduction of CO contamination to efficiently provide to the silicon material with the thermal energy loaded for melting and thereby to shorten the duration of time from the initiation of melting to the completion of melting.

Specifically, the foregoing object can be achieved by taking measures such as increasing the power of the heater for melting, optimizing the arrangement of the heater, optimizing the arrangement of the heat insulator inside the furnace, and if necessary, preliminarily heating the components inside the melting furnace and the like.

For example, when 80 kg of Si material is melted, it can be thoroughly melted by heating for usually about 2-4 hours.

In order to maximize the efficiency of a solar cell, as publicly known, control of p-type or n-type conductivities and control of doping density by appropriate introduction of doping elements are necessary. Doping is accomplished by setting the doping material together with Si material inside the crucible and mixing them together by melting or introducing the doping material into the molten silicon to be melted and mixed therein.

Here, preferably, B (boron) is used as the p-type doping element and P (phosphorus) is used as the n-type doping element. The doping amount is preferably adjusted such that the density of a doping element in the solidified ingot is on the order of 1E16-1E17 [atoms/cm³] (in this case, the specific resistivity of the obtained substrate is about 0.2-2Ω·cm) to achieve the maximum solar cell properties as later described.

Specifically, the adjustment of the doping amount needs to be carried out taking the segregation coefficient (partition coefficient) of each doping element into consideration. To take B (boron) as an example, since the segregation coefficient of B is about 0.8, when the concentration of B in an early solidified portion (bottom portion) of a solidified ingot is desired to be 1E16 [atoms/cm³] the doping amount may be determined so that the concentration of B in the molten liquid is 1E16/0.8=1.25E16 [atoms/cm³].

After this dopant introduction, as shown in FIG. 4 (d), the molten silicon that has been brought into a thoroughly molten state through the foregoing melting process is poured into the mold set inside the furnace as rapidly as possible so as to solidify the molten silicon (casting). At this time, the interior of the furnace has an Ar atmosphere, and controlled so that Ar flow rate is in a range of about 10-100 L/min and Ar gas pressure is in a range of about 1 kPa-100 kPa (atmospheric pressure).

Although the molten silicon is poured into the mold through the injection port 15 provided in a bottom portion of the crucible body 12 in FIG. 4 (d), the molten silicon may be poured into the mold from an upper part of the crucible by inclining the crucible. In this case, there is no need to provide an injection port in the bottom portion of the crucible body 12. It is also possible to pour the molten silicon into the mold from an upper part of the crucible in the manner shown in FIG. 6.

The mold may be formed of carbon material such as graphite or carbon material, or other materials such as, quartz quartz glass, ceramics or the like.

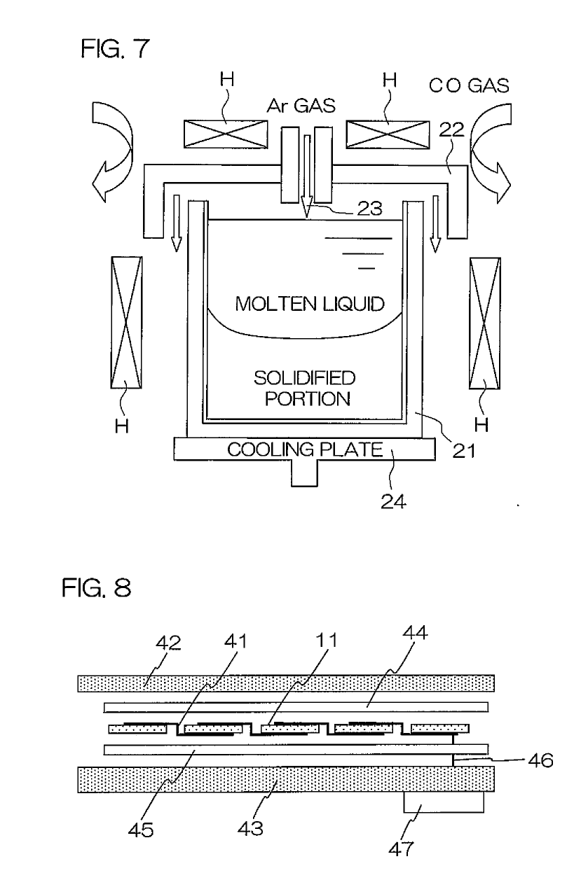

FIG. 7 is a cross-sectional view of the structure of a hermetically sealed mold according to the present invention.

This mold is constituted of a mold body 21 and a detachable lid 22 . . . of the mold. The lid 22 of the mold is formed with an inlet 23 for introducing Ar gas to flow inside the mold. In addition, a clearance is provided between the mold body 21 and lid 22 for allowing the Ar gas to exit the crucible. The component denoted by 24 is a cooling plate disposed in a bottom portion of the mold.

Furthermore, a lid lifting and lowering mechanism (not shown) for attaching and detaching the lid 22 of the mold may be provided inside the melting furnace. This is provided for loading an oxygen supplying source such as quartz powder, quartz flakes or quartz wires into the molten silicon inside the mold as later described. However, arranging the lid 22 to be attachable and detachable is not an indispensable requisite. Instead of the attachable and detachable lid, a hole or mechanism allowing for loading of the oxygen supplying source may be provided in the mold 21 or the lid.

A mold releasing agent is preliminarily applied to the inner wall of the mold so that the ingot can be easily taken out of the mold after solidification and cooling. This mold releasing agent also functions to prevent contact reaction between the mold material and the molten silicon, thereby to prevent the impurities included in the mold material from mixing into the molten silicon.

SiN power may be used for the mold releasing agent. In some cases, an appropriate amount of SiO₂ powder may be mixed with SiN powder to increase the strength of the mold releasing agent so that peeling or falling off of the releasing agent during the pouring/solidifying operation can be effectively prevented. The application of the mold releasing agent to the inner wall of the mold is carried out in a state where the material powder of mold releasing agent and an organic material such as PVA at an appropriate mixing ratio are mixed so that the mixture has viscosity. After it is applied, the organic components are removed by heat treatment.

The solidification of the molten silicon is carried out such that the molten silicon is solidified upward from a bottom section of the mold in one direction (to promote one directional solidification). During this operation, the overall mold-silicon heat flow balance is preferably adjusted. Specifically, removal of heat from the bottom section of the mold is promoted by bringing the cooling plate into contact with the bottom section of the mold, and simultaneously, removal of heat by heat radiation from the top portion of the silicon molten is suppressed. The latter adjustment is carried out by improving the adiabaticity of the upper portion of the molten silicon inside the furnace, or if necessary, applying heat by the heater H.

Concerning the shortening of the time for solidification in the mold, measures including the following may be taken to efficiently remove heat from the bottom section of the mold: increasing the contact area between the cooling plate and mold (for example, forming the structure of the contact area to have projections and depressions in a meshing manner), thinning the cooling plate, increasing the flow rate of cooling medium, thinning the mold bottom section and improving the thermal conductivity thereof (using high density graphite or the like). Furthermore, in some cases, measures for cooling from the side portions of the mold as well as cooling from the mold bottom section may be taken in order to improve heat removing effect even if the one directional solidification is impaired.

When a silicon ingot with the same weight is casted, casting the ingot so that the height thereof is as small as possible and the bottom area of the mold is as large as possible is effective to enhance the heat removing effect. In addition, in order to enhance the thermal conductivity of the mold releasing agent, it is important to apply the mold releasing agent as thin as possible in a dense condition with low porosity.

While removal of heat from the side wall of the mold is not preferable in terms of enhancing one directional solidification, when impurity contamination originated from the mold releasing agent or from the mold through the mold releasing agent is great, it is possible to purposely promote removal of heat from the side wall of the mold (in other words, to accelerate solidification from the side wall) so that the crystalline silicon layer solidified on the inner surface of the mold side wall functions to block diffusion of impurities.

This is carried out on assumption that the crystalline silicon region located at the side wall region of the mold is cut off and removed as cutting chips in the later step of cutting the ingot.

What should be avoided here is carbon contamination of the molten silicon by the CO gas inside the furnace as already described referring to the melting process. For the purpose of reduction of carbon contamination, as already described referring to the melting process, it is important to minimize the CO partial pressure inside the furnace by increasing the rate of gas discharge, and minimize the time taken to complete solidification.

In order to reduce the CO partial pressure, as shown in FIG. 7, it is very effective to use the hermetically sealed mold that is capable of effectively suppressing and blocking contact between the CO gas and molten silicon. It is needless to say that general conditions for reducing CO partial pressure also need to be readily satisfied as already described referring to the melting process.

When silicon is solidified using this hermetically sealed mold, the effect of reducing the CO partial pressure inside the furnace can be obtained. Therefore, contact between the molten liquid and CO gas can be suppressed without purposely increasing the Ar flow rate. Therefore, carbon contamination can be efficiently suppressed to a minimum with Ar gas at a small flow rate.

Here, the most characteristic thing of this embodiment of the present invention is the control of oxygen concentration in the molten liquid during the solidification process.

This is because the oxygen concentration in the molten liquid determines the oxygen concentration in silicon after solidification, that is, the interstitial oxygen concentration [Oi] in the silicon ingot (or in a silicon substrate after slicing).

In conventional casting techniques, it has been inevitable that oxygen concentration in the molten silicon during the solidification process drops exponentially as solidification proceeds due to evaporation of SiO gas at an extremely high rate.

This is because the material in contact with the molten liquid changes from quartz in the melting step to a SiN mold releasing agent, which cuts off the oxygen supply to the molten liquid to proceed only the evaporation of SiO gas unilaterally.

For example, when 80 kg of molten silicon is solidified in one direction for about 8 hours, the concentration of oxygen present in the initial molten silicon immediately after the molten silicon is poured into the mold is about 1E18[atoms/cm³], however, it decreases rapidly to 2E17[atoms/cm³] or so in an early stage where the solidification rate is about 20%, and further decreases to 4E16[atoms/cm³] or so at a solidification rate of about 40%. The “solidification rate” here refers to a location in an ingot defined along the direction of solidification. The earliest solidified bottom section of an ingot is defined as 0% in solidification rate, and the latest solidified top section of the ingot is defined as 100% in solidification rate.

As discussed so far, it has been impossible to control the interstitial oxygen concentration [Oi] to be not less than 2E17[atoms/cm³] almost throughout the height of an ingot by conventional polycrystalline silicon casting methods.

On the other hand, in the casting method according to this embodiment, oxygen is purposely supplied to the molten liquid in the solid (SiO₂) form. This enables control of the oxygen concentration in the molten liquid.

That is, in this embodiment, an appropriate amount of quartz powder is purposely loaded, or an appropriate amount of quartz flakes or fibrous quartz wires are immersed into the molten liquid being solidified. In this manner, oxygen in the molten liquid is controlled over the whole period of the solidification process.

Since oxygen is not supplied in the form of gas in this method, this is also advantageous in that CO gas generation caused by the reaction between the carbon material in the furnace and gas including oxygen can be avoided.

Moreover, when this method is combined with the aforementioned hermetically sealed mold, because of the hermetically sealed mold, almost no carbon contamination of molten silicon by CO gas occurs even if CO gas is generated due to the reaction between the SiO gas that continues to evaporate and the carbon material inside the furnace.

In addition, since the oxygen supply into the molten liquid works to promote removal of carbon from the molten liquid by CO gas evaporation, it is also advantageous for reducing the carbon concentration in the molten liquid.

The amount of quartz to be loaded is preferably about 0.00005 g/min (0.003 g/hr) or more per 1 kg of silicon, more preferably, 0.0001 g/min (0.006 g/hr) or more. When the amount of quartz to be loaded is less than this value, the amount of oxygen evaporation becomes too large to achieve the desired oxygen concentration, leading to decrease in crystal strength. In addition, in such a case, the carbon removing effect may not work, and the quality may deteriorate.

The upper limit of the amount of quartz to be loaded is preferably in the range of 0.001 g/min (0.06 g/hr)-0.01 g/min (0.6 g/hr). When more amount of quartz is loaded, oxygen precipitation is more likely to be induced, and this tends to incur degradation in crystal quality.

Specifically, taking a case where about 80 kg of molten silicon is solidified inside a cubic mold of about 30 cm×30 cm×30 cm for about 8 hours as an example, the oxygen supply is preferably about 0.004 g/min (0.24 g/hr) or more in quartz SiO₂ weight, more preferably, 0.008 g/min (0.48 g/hr) or more.

Since SiO evaporation amount is proportional to the contact area between the molten silicon and the gas inside the furnace (and therefore the volume of the molten silicon is basically irrelevant to the SiO evaporation amount), when the mold shape is different from the foregoing one, for example, when it is not hermetically sealed, the amount of oxygen supply needs to be controlled taking this into account.

While the description so far has been given of cases where the casting method is used for molding the silicon ingot, the method is not limited to this. That is, the present invention is applicable to other methods including an in-mold melting and solidification method in which the material is melted inside the mold and solidified as it is, a sheet silicon forming method where molten silicon is introduced on a graphite material in a sheet-like shape so as to be solidified, the ribbon-to-ribbon method where silicon is solidified while being pulled from molten silicon in a sheet-like manner.

Now, the in-mold melting and solidification method is described as one example. A mold with a structure similar to that shown in FIG. 7 is used.

Silicon is loaded into this mold, which is covered with a lid 22 to be substantially hermetically sealed, then it is subjected to a heating process in which silicon is melted in the foregoing mold. At this time, in order to avoid cooling by a cooling plate 24, it is preferable to provide a lifting and lowering mechanism in the cooling plate 24 so as to move the cooling plate 24 away from the mold, or to stop the flow of the cooling medium. In the same manner described above, owing to the hermetically sealing effect of the mold, the CO partial pressure inside the mold can be reduced, so that carbon contamination of silicon can be suppressed.

After the molten silicon is completely melted, the molten silicon is subjected to the solidification process, where it is solidified in one direction, upward from a bottom section of the mold.

During this solidification process, in the same way as described above, an oxygen supplying source including quartz powder, quartz flakes or quartz wires is loaded into the molten silicon inside the mold so as to replenish oxygen insufficient in the molten liquid.

When the silicon is thoroughly cooled, the mold is removed to take out the ingot.

Hereinafter, a description will be given of a cell fabrication process for forming a solar cell element using a polycrystalline silicon substrate of the present invention.

First, a polycrystalline silicon substrate is prepared as one conductivity-type semiconductor substrate by slicing a p-type polycrystalline silicon ingot that is doped with B at a concentration of about 1E16-1E17 [atoms/cm³] in the foregoing polycrystalline silicon casting process. Here, the thickness of the substrate is preferably 300 μm or less, more preferably 250 μm or less, and further more preferably 150 μm or less.

When the oxygen concentration in the p-type silicon substrate is larger than 2E17 [atoms/cm³], it is preferable for obtaining good properties that, a heat treatment process for heating this substrate in a reducing atmosphere is carried out prior to the later described thermal diffusion process for forming an opposite conductivity-type region 4, so that a low oxygen concentration region with an oxygen concentration of less than 2E17 [atoms/cm³] is formed in a surface layer region of the substrate.

This heat treatment may be carried out in a reducing atmosphere (e.g. Ar, N₂, H₂ atmosphere or the like) at 1200° C. for 4 minutes to 1000° C. for 90 minutes, by which oxygen is diffused outward, so that a low oxygen concentration region can be formed in a surface layer of the substrate. Here, if forming a deeper low oxygen concentration region is desired, the treatment time may be prolonged. In order to promote the outward oxygen diffusion, a hydrogen atmosphere is particularly preferable for the reducing atmosphere.

As another process for forming a low oxygen concentration region in a surface layer region of the substrate, a laser recrystallization process may be carried out prior to the later described thermal diffusion process for forming an opposite conductivity-type region 4a, in which a surface layer region of the substrate is irradiated with laser beams so as to recrystallize the surface layer region after melting, thereby forming a low oxygen concentration region with oxygen concentration of less than 2E17 [atoms/cm³] in the surface layer region of the substrate.

In this process, since oxygen rapidly evaporates and deoxidizes in the form of SiO gas from the region melted by the laser irradiation, reduction of oxygen concentration can be more efficiently accomplished than the foregoing way of outwardly diffusing oxygen by a heat treatment. In addition, since heat treatment of the substrate at a high temperature is unnecessary and the processing time is relatively short, this process is advantageous for cost reduction. The region to which laser recrystallization is applied is a surface layer region of the substrate formed with the surface collector electrodes 1, and preferably, it includes regions of both of the bus bar electrodes 1a and finger electrodes 1b. However, only the regions of the bus bar electrodes 1a may be irradiated selectively. In this manner, it is possible to selectively control the oxygen concentration in major parts of the pn junction depletion zone beneath the surface electrodes.

As described above, when a low oxygen concentration region with oxygen concentration of less than 2E17 [atoms/cm³] is formed in the surface layer region of the substrate to be later formed with a pn junction, the oxygen concentration of the major depletion region after the cell fabrication process can be suppressed to be less than 1E18 [atoms/cm³] even if there is oxygen diffusion inside the substrate during the cell fabrication process. Therefore, property deterioration due to undergoing the cell fabrication process can be effectively prevented.

The reason that suppressing the oxygen concentration to less than 1E18 [atoms/cm³] is preferable is that when the oxygen concentration exceeds this value, oxygen precipitation sharply increases.

When a low oxygen concentration region is formed by the foregoing heat treatment or laser recrystallization process, the thickness thereof is preferably 1.0 μm or more. The later described opposite conductivity-type region 4 is formed by thermally diffusing P, which is a doping element of the conductivity opposite to that of the low oxygen concentration region, and usually formed to have a thickness of about 0.2-0.5 μm and forms a pn junction region. Since the depletion zone of the pn junction has a thickness of about 0.4 μm, forming the low oxygen concentration region to have a thickness of 1.0 μm or more further ensures that the oxygen concentration is less than 1E18 [atoms/cm³] in the depletion region on the side of the p-type bulk region 5 after going through all the cell fabrication steps.

As in the present invention, when the carbon concentration is an order of magnitude smaller than those in conventional cases, even if the oxygen concentration in the substrate exceeds 2E17[atoms/cm³], degradation of substrate quality due to undergoing the cell fabrication process, in other words, the amount of oxygen precipitation can be suppressed to a minute degree. For this reason, as far as a polycrystalline silicon substrate of the present invention is used, the aforementioned reduction of oxygen concentration in the substrate surface layer region is desirable but not indispensable.

Thereafter, in order to remove mechanically damaged and contaminated layers in substrate surface layer regions due to the slicing, the surface layer regions on the front surface side and back surface side are etched to a depth of about 10-20 μm with NaOH, KOH, or a mixed solution of hydrofluoric acid and nitric acid and then cleaned with pure water or the like.

Then, an asperity (roughed) texture having a light reflectivity-reducing function is formed on the front surface side of the substrate serving as light-entrance surface (not shown). For forming the asperity texture, the anisotropic wet etching process with use of alkali solution such as NaOH that is used for the foregoing removal of surface layer regions may be used. However, when the silicon substrate is a polycrystalline silicon substrate fabricated by the casting method or the like, the crystal plane orientation inside the substrate surface varies randomly from crystal grain to crystal grain, making it difficult to evenly form a good asperity texture capable of effectively reducing light reflectivity allover the substrate. In such a case, gas etching, for example, RIE (Reactive Ion Etching) may be used, so that a good asperity texture can be formed evenly allover the substrate.

Meanwhile, the same effect can be obtained by carrying out the foregoing heat treatment or the laser recrystallization process for forming a low oxygen concentration region in a surface layer region of the substrate after this asperity texture formation process.

Subsequently, an n-type, opposite conductivity-type region 4 is formed. P (phosphorus) is preferably used as the n-type doping element. The doping concentration is controlled to be 1E18[atoms/cm³]−5E21 [atoms/cm³] to form a n⁺-type region with a sheet resistance of about 30-300Ω/□. A pn junction region is thus formed between this region and the foregoing p-type bulk-region. Here, the pn junction region includes a depletion zone extending on the side of the p-type bulk region and a depletion zone extending on the side of the opposite conductivity-type region 4.

The formation method of the opposite conductivity-type region 4 is carried out by thermal diffusion method using gasified POCl₃ (phosphorous oxychloride) as the diffusion source such that the doping element P is diffused into the surface layer region of the p-type silicon substrate at a temperature of about 700-1000° C. Here, the diffusion layer is formed to have a thickness of about 0.2-0.5 μm, which can be accomplished by controlling the temperature and time for diffusion so as to form the desired dope profile. In addition, the sheet resistance is preferably about 45-100Ω/□, and more preferably, about 65-90Ω/□.

While in the foregoing thermal diffusion process using a general gas diffusion source, a diffusion region is formed also on the opposite surface of the target surface, this region may be removed later by etching. This removal of the opposite conductive-type region 4 on the side other than the surface side of the substrate is carried out by applying a resist film on the surface side of the silicon substrate and then removing by etching with use of a mixed solution of hydrofluoric and acid nitric acid, and thereafter, removing the resist film. As described later, when a p⁺-type region 7 (BSF region) in the back surface is formed with aluminum paste, since aluminum as p-type doping element can be diffused at an adequate concentration to an adequate depth, influence of the shallow n-type diffusion layer that has been already formed can be negligible. Therefore, it is not particularly necessary to remove the n-type diffusion layer formed on the back surface side.

The process for forming the opposite conductivity-type region is not limited to the thermal diffusion process, but a thin film deposition technique and its conditions may also be used to form a hydrogenated amorphous silicon film or a crystalline silicon film including a microcrystalline silicon film at temperatures of 400° C. or less.

As mentioned above, where a thin film deposition technique is used instead of the thermal diffusion process to form the opposite conductivity-type region 4 at a low temperature, since diffusion of oxygen on the substrate side is negligible in this process, oxygen concentration in the substrate is allowed to about 1E18[atoms/cm³] at the maximum. In addition, even when the oxygen concentration in the substrate is higher than this and the foregoing heat treatment or laser recrystallization is applied to the surface layer region of the substrate, the oxygen concentration is only required to be 1E18[atoms/cm³] or less within the range where the depletion zone of pn junction is formed. Therefore, the value required for the oxygen concentration in the substrate before pn junction formation can be far more lenient. However, as far as a polycrystalline silicon substrate of the present invention is used, the upper limit value of oxygen concentration mentioned above is not requisite.

When the opposite conductivity-type region 4 is formed by a thin film deposition technique, it is necessary to determine the order of formation processes taking the temperatures for the respective processes into consideration so that the later processes are carried out at lower temperatures.

When the opposite conductivity-type region 4 is formed using a hydrogenated amorphous silicon film, the thickness thereof is 50 nm or less, preferably 20 nm or less. When it is formed using a crystalline silicon film, the thickness thereof is 500 nm or less, preferably 200 nm or less. When the opposite conductivity-type region 4 is formed by the foregoing thin film deposition technique, it is effective for improving the properties by forming an i-type silicon region to have a thickness of 20 nm or less between the p-type bulk region and the opposite conductivity-type region 4.

Subsequently, an antireflective film 6 is formed. The antireflective film 6 may include a Si₃N₄ film, TiO₂ film, SiO₂ film, MgO film, ITO film, SnO₂ film, ZnO film or the like. The thickness thereof is determined according to the material so as to realize a non-reflective condition to incident light (if the index of refraction of the material is represented by n and the wavelength of the spectrum range desired to be non-reflective is represented by λ, optimum film thickness of the antireflective film 6 is expressed as (λ/n)/4=d). For example, in the case of a generally used Si₃N₄ film (n=approx.2), when the wavelength to which the film is desired to be non-reflective is determined as 600 nm taking the sun light spectrum characteristics into account, the thickness may be determined to be about 75 nm.

For the formation of the antireflective film 6, the PECVD method, vapor deposition method or sputtering method is performed at a temperature of about 400-500° C. when the pn junction region is formed by thermal diffusion, and at a temperature of about 400° C. or less when it is formed by thin film deposition method. When the surface collector electrodes 1 are not formed by the later described fire through method, the antireflective film 6 is patterned in a predetermined patterning. The patterning may be carried out by (wet or dry) etching with use of resist as a mask, or by preliminarily forming a mask during the formation of the antireflective film 6 and removing the mask after the formation of the antireflective film 6. On the other hand, when the so-called fire through process is used, in which the electrode material for the surface collector electrodes 1 is directly applied onto the antireflective film 6 thereby to electrically connecting the surface collector electrodes 1 and the opposite conductivity-type region 4, the foregoing patterning is not necessary. This Si₃N₄ film exerts a surface passivation effect during the formation thereof, and a bulk passivation effect during the subsequent heat treatment process, which, together with the antireflective function, are effective to improve the electric properties of the solar cell element.

Subsequently, a p⁺-type region (BSF region) is formed. Specifically, aluminum paste is formed in which 10-30 parts by weight of an organic vehicle and 0.1-5 parts by weight of glass frit, respectively, are added to 100 parts by weight of aluminum powder into a paste, and printed, for example, by screen printing and dried, and thereafter it is heat treated in a range of 600-850° C. for several seconds to several ten minutes. This forms a p⁺-type region 7 (BSF region) that prevents recombination of carriers generated in the back surface by diffusion of aluminum into the silicon substrate. The aluminum doping concentration in the p⁺-type region 7 is about 1E18[atoms/cm³]−5E21[atoms/cm³].

In the metal component in this paste that is not used to form the p⁺-type region 7 and remains on the p⁺-type region 7 may be used as a part of the back surface collector electrode 8. In this case, removing the remaining component using hydrochloric acid or the like is not particularly necessary. While the present specification addresses that there is a back surface collector electrode 8 composed mainly of aluminum remaining on the p⁺-type region, when it is removed, an alternative electrode material may be employed. As the alternative electrode material, using silver paste described later is preferable to form the back surface collector electrode 8 in order to enhance the reflectivity of long wavelength light that has arrived at the back surface. Additionally, B (boron) may also be used as the p-type doping element.

When this p⁺-type region 7 is formed by the print and bake process, as described previously, it is no longer necessary to remove the n-type region that is formed on the back surface side of the substrate simultaneously with the formation of the opposite conductivity-type region 4 on the surface side of the substrate.

Furthermore, it is also possible to form this p⁺-type region 7 (on the back surface side) by the thermal diffusion method with use of gas instead of the print and bake method. In this case, the p⁺-type region 7 is formed using BBr₃ as the diffusion source at a temperature of about 800-1100° C. Here, a diffusion barrier such as an oxide film is preliminarily formed on the opposite conductivity-type region 4 (on the surface side) that has been already formed. If this process causes damage to the antireflective film 6, it is possible to carry out this process prior to the formation of the antireflective film 6. The doping element concentration is about 1E15 [atoms/cm³]−5E21 [atoms/cm³]. This allows a Low-High junction to be formed between the p-type bulk region and p⁺-type region.

The method for forming the p⁺-type region is not limited to the print and bake method and the thermal diffusion method with use of gas, but it may be formed, for example, by a thin film deposition technique to form a hydrogenated amorphous silicon film or a crystalline silicon film including microcrystalline silicon phases at a substrate temperature of about 400° C. or less. In particular, when the pn junction region is formed by a thin film deposition technique, the formation of the p⁺-type region is also carried out by the thin film deposition technique. In this case, the film thickness is about 10-200 nm. In this case, forming an i-type silicon region (not shown) with a thickness of about 20 nm or less between the p⁺-type region and the p-type bulk region is effective to improve the properties.

However, when this is formed by a thin film deposition technique, it is desirable to determine the order of formation processes taking the temperatures for the respective processes described below into consideration so that the later processes are carried out at lower temperatures.

Subsequently, surface collector electrodes 1 and back surface output electrodes 9 are formed by applying silver paste to the surface and back surface of the substrate and then baking. Silver paste prepared by adding 10-30 parts by weight of an organic vehicle and 0.1-5 parts by weight of glass frit, respectively, to 100 parts by weight of silver power is printed, for example, by screen printing, and dried, and simultaneously baked at 600-300° C. for several seconds to several minutes so as to burn into the printed surface.

While it is preferred in terms of cost reduction to bake the surface collector electrodes 1 and back surface output electrodes 9 simultaneously (at once), sometimes carrying out two times to bake them separately is preferable, when, in particular, the electrode strength of the back surface electrodes is taken into consideration (in such a case, for example, surface collector electrodes 1 are printed and baked first and then back surface output electrodes 9 are printed and baked).

Additionally, although methods other than the print and bake method including vacuum deposition method such as sputtering, vapor deposition may be used, in particular, in a print and bake method with use of paste, by the so-called fire through method, metal containing paste to form the surface collector electrodes 1 is directly printed on the antireflective film 6 without patterning thereon and baked so that electrical contact is established between the surface collector electrodes 1 and the opposite conductivity-type region 4, which is very effective to reduce the production cost. The formation of the surface collector electrodes 1 may be carried out prior to the formation of the p⁺-type region 7 on the back surface side.

In order to particularly enhance bonding strength between the electrodes and semiconductor regions, it is preferable that a little amount of oxide component such as TiO₂ is included in the paste in the print and bake method with use of paste, and a metal layer composed mainly of Ti is inserted in the interfaces between the electrodes and semiconductor regions in a vacuum deposition method. In the case of the back surface electrodes, the thickness of the metal layer composed mainly of Ti is preferably 5 nm or less so as to suppress decrease in reflectivity due to the insertion of the metal layer. The back surface collector electrode 8 is preferably formed on the entire area of the back surface of the substrate for increasing the reflectivity to long wavelength light that arrives at the back surface.

When the back surface collector electrode S and the back surface output electrodes 9 are overlapped to be thick, cracking and peeling are prone to occur. Therefore, it is preferable that after the back surface output electrodes 9 for extracting output are formed, the back surface collector electrode 8 is formed so as not to cover the back surface output electrodes 9 while allowing electrical conduction therebetween. In addition, the order of formation of the back surface output electrodes 9 and back surface collector electrodes 8 may be reversed. It is also possible for the back surface electrodes to have a structure different from the foregoing structure, which includes bus bar sections and finger sections composed mainly of silver as the surface collector electrodes 1.

In cases where the opposite conductivity-type region 4 and p⁺-type region 7 are formed by a thin film deposition technique, it is possible to form the surface collector electrodes 1, back surface collector electrode 8 and back surface output electrodes 9 by printing method, sputtering method, vapor deposition method and the like. However, the temperature for the process should be 400° C. or less in consideration of damage to the thin film layer.

Finally, a solder region is formed on the surface collector electrodes 1 and back surface electrodes by solder dipping treatment as the need arises (not shown). When the electrodes are intended to be solderless electrodes without using solder material, the solder dipping treatment is omitted.

Through these steps, a high quality polycrystalline silicon substrate of the present invention can be realized, and moreover, a solar cell element and a solar cell module with high properties using this substrate can be realized.

Because a single solar cell element as a photoelectric conversion element that is produced in the foregoing way can output only small electric power usually, a plurality of solar cell elements are generally connected in series or in parallel and used as a solar cell module. And further, a plurality of such solar cell modules are combined to constitute a structure capable of generating practical electric power.

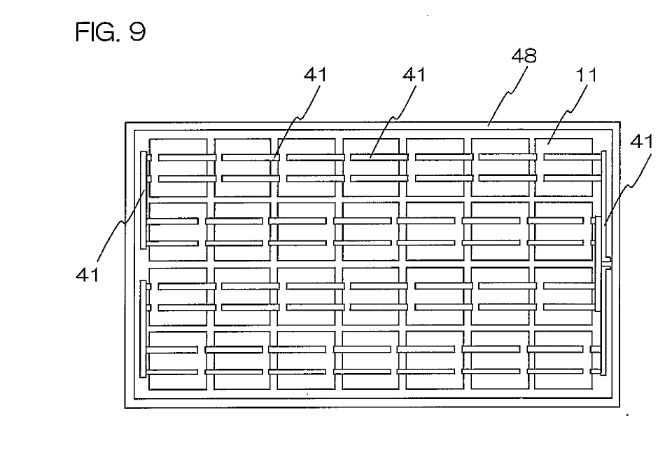

A typical structure of a solar cell module is shown in FIGS. 8 and 9.

FIG. 8 is a cross-sectional view showing the structure of a typical solar cell module, and FIG. 9 is a top view of this solar cell module viewed from the light-entrance surface side.

There are shown a solar cell element 11, a wiring member 41 electrically connecting solar cell elements, a transparent member 42 formed of glass or the like, a back surface protecting member 43 including polyethyleneterephtalate (PET) or metal foil sandwiched by poly vinyl fluoride resin (PVF), a surface side filler 44 including transparent ethylene vinyl acetate copolymer (EVA) or the like, a back side filler 45 formed of EVA or the like, output extracting wiring 46, a terminal box 47, and a frame 48 of the solar cell module.

As shown in FIG. 8, the surface side filler 44 including transparent ethylene vinyl acetate copolymer (EVA) or the like, a plurality of solar cell elements 11 in which the surface electrodes and back surface electrodes of adjacent solar cell elements are alternately connected to one another by the wiring member 41, the back side filler 45 formed of EVA or the like, and the back surface protecting member 43 including polyethyleneterephtalate (PET) or metal foil sandwiched by poly vinyl fluoride resin (PVF) are successively laminated the transparent member 42, and then evacuated and pressed under heat inside a laminator so as to be integrated into one body, thereby completing a solar cell module.

Subsequently, the frame 48 made of aluminum or the like is fit to the periphery according to need. Furthermore, one end of the electrode of the first solar cell element and one end of the electrode of the last solar cell element in the series connected plurality of elements are connected to the terminal box 47 as an output extracting section through the output extracting wiring 46.

As the wiring member 41 for connecting these solar cell elements, generally, about 0.1-0.2 mm thick, 2 mm wide copper foil whose entire surface is coated with solder material is cut into wires in predetermined lengths, which are soldered onto the electrodes of the solar cell elements.

While specific embodiments of the present invention have been heretofore described, implementation of the present invention is not limited to the foregoing embodiments.

For example, although the description so far has been given of solar cell using p-type silicon substrate, the present invention is applicable to solar cell using n-type silicon substrate produced through similar processes when the polarity is reversed.

In addition, while the foregoing description has been given of single junction type solar cell, the present invention is applicable to multi-junction type solar cell formed by laminating thin film layers that is composed of multiple semiconductor layers on a bulk substrate junction device.

While the foregoing description has been given of bulk-type silicon solar cell by way of example, the present invention is not limited to this, but may be embodied in other forms without departing from the principles and objects of the invention. That is, the present invention is applicable to photoelectric conversion elements in general including those other than solar cells such as optical sensors as far as it is a photoelectric conversion element including a pn junction containing crystalline silicon having a light-entrance surface as a structural element which collects photo generated carriers generated in the semiconductor region by light incident on the light-entrance surface as electric current.

### EXAMPLE

Hereinafter, a description will be given of the results of experiments to investigate the relationship between the amount of purposely supplied oxygen and the cell properties on solar cell elements using polycrystalline silicon substrates produced according to the foregoing embodiments.

### <Casting>

Casting was carried out for two types; one in which an open crucible and an open mold were used (Ingot No. 1) and one in which the hermetically sealed crucible shown in FIG. 5 and the hermetically sealed mold shown in FIG. 7 were used (Ingot Nos. 2-6).

The amount of silicon material used was 80 kg. As the doping condition of boron, the amount thereof was controlled so that specific resistivity p b in a bottom section of the ingot was 2 Ω·cm.

The conditions were controlled such that the time for the melting process was 4 hours (in which the substantial melt existing time from the initiation of melting to the completion of melting was about 2 hours), the time for the solidification process was 7.5 hours, Ar gas pressure inside the furnace was 10 kPa, and Ar gas flow rate was 50 L/min.

The intentional oxygen supply into the molten liquid was carried out by dropping quartz powder into the molten silicon in a small amount at time in regular intervals.

The weights of quartz powder supply per unit time [g/min] were as follows:

Ingot No. 1: 0.000 [g/min]
Ingot No. 2: 0.000 [g/min]
Ingot No. 3: 0.002 [g/min]
Ingot No. 4: 0.004 [g/min]
Ingot No. 5: 0.008 [g/min]
Ingot No. 6: 0.016 [g/min]

The ingots casted in this way were cut and sliced at the locations of the respective solidification rates to obtain sheet-like polycrystalline silicon substrates with thicknesses of about 250 μm, and sizes of 150 mm×150 mm.

### <Impurity Analysis>

Substrates for impurity concentration analyses were obtained by extracting one from each of the locations of the solidification rates 20%, 40%, 60%, 80% in the respective ingots, which were subjected to desired analyses by FT-IR (Fourier Transform Infrared Spectrophotometer) and SIMS (Secondary Ion Mass Spectrometry).

Interstitial oxygen concentrations [Oi] in the crystalline silicon substrates were measured using FT-IR, and total carbon concentrations [C] and total nitrogen concentrations [N] were measured using SIMS.

Here, nitrogen in the crystalline silicon was thought to originate from SiN that is the main component of the mold releasing agent.

SIMS is a method in which a primary ion beam (oxygen, cesium or the like) narrowly focused by acceleration is projected to a specimen in a vacuum atmosphere, and secondary ions are drawn from particles that are shot out from the surface of the specimen by the sputtering to be subjected to mass spectrometry. Absolute concentration values are calculated by comparing with standard specimens. The conditions for measurements in this example were as follows:

Apparatus for measurement: IMS-4f produced by Cameca Instrument Inc.
Primary ion species: Cs⁺
Primary ion acceleration voltage: 14.5 kV
Primary ion current: 120 nA
Raster area: 125 μm
Area for analysis: 30 μmφ
Degree of vacuum for measurement: 1E-7

FT-IR is constituted of a light source section, an interferometer, specimen section, detection section, and data processing section. Light emitted from the light source section enters the interferometer, and passes through the specimen as an interference wave. In passing, light with a specific oscillation frequency corresponding to the vibration energy of atoms or an atomic group in the molecules constituting the specimen is absorbed. The signal obtained by the detector is Fourier-transformed to provide infrared spectrum specific to the element. Peaks of interstitial oxygen in silicon and substitutional carbon appear at 1106 cm⁻¹ and at 607 cm⁻¹, respectively (See Japanese Unexamined Patent Publication No: 2003-226597 and Japanese Unexamined Patent Publication No. 9-297101). By comparing these peaks with those of a standard specimen, absolute concentrations are measured. The conditions for measurements in this case were as follows:

Apparatus for measurement: IFS-66v/S produced by Bruker Optics K.K.
Light source: Silicon C

### Detector: DTGS

### Beam Splitter Ge/KBr

Resolution: 8 cm⁻¹
Number of times of integration: 1024
Measurement mode: Transmissive
Measurement area: 5 mmφ

Impurity concentration analysis was carried out for the sample substrates of Ingot Nos. 1-6 on four points of each substrate excluding 1 cm wide substrate periphery zone.

The respective concentrations [Oi] at these four points and averages thereof, the respective concentrations [C] at these 4 points and averages thereof, and the respective concentrations [N] at these four points and averages thereof were determined, the results of which are shown in Tables 1 and 2.

TABLE 1

| | | Solidification rate | | | |
|---|---|---|---|---|---|
| | | 20% | 40% | 60% | 80% |
| No. 1 | | | | | |
| [Oi] | 1 | 2.3E+17 | 6.6E+16 | 3.2E+16 | 1.2E+16 |
| | 2 | 2.5E+17 | 6.8E+16 | 3.2E+16 | 1.3E+16 |
| | 3 | 2.5E+17 | 6.7E+16 | 3.0E+16 | 1.2E+16 |
| | 4 | 2.4E+17 | 6.8E+16 | 3.5E+16 | 1.2E+16 |
| | Ave | 2.4E+17 | 6.7E+16 | 3.2E+16 | 1.2E+16 |
| [C] | 1 | 2.4E+17 | 3.9E+17 | 4.3E+17 | 4.0E+17 |
| | 2 | 2.4E+17 | 3.8E+17 | 4.3E+17 | 3.8E+17 |
| | 3 | 2.3E+17 | 4.0E+17 | 4.1E+17 | 3.6E+17 |
| | 4 | 2.2E+17 | 3.9E+17 | 4.2E+17 | 3.8E+17 |
| | Ave | 2.3E+17 | 3.9E+17 | 4.2E+17 | 3.8E+17 |
| [N] | 1 | 3.2E+15 | 4.6E+15 | 4.5E+15 | 4.3E+15 |
| | 2 | 3.3E+15 | 5.1E+15 | 4.0E+15 | 4.3E+15 |
| | 3 | 3.4E+15 | 4.7E+15 | 4.5E+15 | 4.0E+15 |
| | 4 | 3.3E+15 | 4.8E+15 | 4.1E+15 | 4.3E+15 |
| | Ave | 3.3E+15 | 4.8E+15 | 4.3E+15 | 4.2E+15 |
| No. 2 | | | | | |
| [Oi] | 1 | 3.2E+17 | 1.1E+17 | 4.4E+16 | 2.2E+16 |
| | 2 | 3.2E+17 | 1.0E+17 | 4.5E+16 | 2.1E+16 |
| | 3 | 3.0E+17 | 1.0E+17 | 4.4E+16 | 2.2E+16 |
| | 4 | 3.4E+17 | 1.2E+17 | 4.7E+16 | 2.2E+16 |
| | Ave | 3.2E+17 | 1.1E+17 | 4.5E+16 | 2.2E+16 |
| [C] | 1 | 2.1E+16 | 3.2E+16 | 4.0E+16 | 1.0E+17 |
| | 2 | 2.1E+16 | 3.2E+16 | 4.0E+16 | 1.0E+17 |
| | 3 | 2.0E+16 | 3.1E+16 | 4.2E+16 | 1.0E+17 |
| | 4 | 2.0E+16 | 3.0E+16 | 4.0E+16 | 1.0E+17 |
| | Ave | 2.1E+16 | 3.1E+16 | 4.0E+16 | 1.0E+17 |
| [N] | 1 | 3.2E+15 | 4.4E+15 | 4.1E+15 | 4.1E+15 |
| | 2 | 3.7E+15 | 4.4E+15 | 4.4E+15 | 4.0E+15 |
| | 3 | 3.2E+15 | 5.0E+15 | 4.4E+15 | 4.1E+15 |
| | 4 | 3.5E+15 | 4.7E+15 | 3.9E+15 | 4.1E+15 |
| | Ave | 3.4E+15 | 4.6E+15 | 4.2E+15 | 4.1E+15 |
| No. 3 | | | | | |
| [Oi] | 1 | 3.5E+17 | 1.5E+17 | 1.0E+17 | 5.9E+16 |
| | 2 | 3.6E+17 | 1.5E+17 | 9.2E+16 | 6.4E+16 |
| | 3 | 3.5E+17 | 1.5E+17 | 8.4E+16 | 6.4E+16 |
| | 4 | 3.8E+17 | 1.5E+17 | 9.2E+16 | 6.9E+16 |
| | Ave | 3.6E+17 | 1.5E+17 | 9.2E+16 | 6.4E+16 |
| [C] | 1 | 1.7E+16 | 3.4E+16 | 5.1E+16 | 1.1E+17 |
| | 2 | 1.9E+16 | 3.2E+16 | 5.5E+16 | 1.0E+17 |
| | 3 | 2.0E+16 | 3.2E+16 | 5.2E+16 | 1.0E+17 |
| | 4 | 2.0E+16 | 3.0E+16 | 5.0E+16 | 1.0E+17 |
| | Ave | 1.9E+16 | 3.2E+16 | 5.2E+16 | 1.0E+17 |
| [N] | 1 | 3.4E+15 | 4.5E+15 | 4.2E+15 | 3.9E+15 |
| | 2 | 3.2E+15 | 4.7E+15 | 4.3E+15 | 3.9E+15 |
| | 3 | 3.4E+15 | 4.4E+15 | 4.7E+15 | 4.6E+15 |
| | 4 | 3.2E+15 | 4.3E+15 | 4.1E+15 | 4.3E+15 |
| | Ave | 3.3E+15 | 4.5E+15 | 4.3E+15 | 4.2E+15 |

TABLE 2

| | | Solidification rate | | | |
|---|---|---|---|---|---|
| | | 20% | 40% | 60% | 80% |
| No. 4 | | | | | |
| [Oi] | 1 | 3.6E+17 | 1.8E+17 | 1.3E+17 | 1.1E+17 |
| | 2 | 4.2E+17 | 1.8E+17 | 1.3E+17 | 1.1E+17 |
| | 3 | 4.2E+17 | 2.1E+17 | 1.2E+17 | 1.1E+17 |
| | 4 | 3.9E+17 | 1.9E+17 | 1.4E+17 | 1.1E+17 |
| | Ave | 4.0E+17 | 1.9E+17 | 1.3E+17 | 1.1E+17 |
| [C] | 1 | 1.9E+16 | 1.9E+16 | 3.9E+16 | 9.2E+16 |
| | 2 | 2.1E+16 | 1.9E+16 | 3.7E+16 | 9.2E+16 |
| | 3 | 2.1E+16 | 1.8E+16 | 3.8E+16 | 9.5E+16 |
| | 4 | 2.0E+16 | 2.0E+16 | 4.0E+16 | 9.0E+16 |
| | Ave | 2.0E+16 | 1.9E+16 | 3.8E+16 | 9.2E+16 |
| [N] | 1 | 3.3E+15 | 4.5E+15 | 4.2E+15 | 4.3E+15 |
| | 2 | 3.3E+15 | 4.1E+15 | 4.4E+15 | 4.0E+15 |
| | 3 | 3.5E+15 | 4.8E+15 | 4.2E+15 | 4.1E+15 |
| | 4 | 3.1E+15 | 4.2E+15 | 4.0E+15 | 4.0E+15 |
| | Ave | 3.3E+15 | 4.4E+15 | 4.2E+15 | 4.1E+15 |
| No. 5 | | | | | |
| [Oi] | 1 | 4.8E+17 | 2.8E+17 | 2.2E+17 | 2.0E+17 |
| | 2 | 4.5E+17 | 2.9E+17 | 2.3E+17 | 2.0E+17 |
| | 3 | 4.7E+17 | 2.8E+17 | 2.5E+17 | 2.3E+17 |
| | 4 | 4.5E+17 | 2.7E+17 | 2.2E+17 | 2.1E+17 |
| | Ave | 4.6E+17 | 2.8E+17 | 2.3E+17 | 2.1E+17 |
| [C] | 1 | 1.8E+16 | 3.2E+16 | 4.1E+16 | 9.9E+16 |
| | 2 | 1.7E+16 | 3.0E+16 | 4.3E+16 | 9.4E+16 |
| | 3 | 1.8E+16 | 2.9E+16 | 4.1E+16 | 9.8E+16 |
| | 4 | 2.0E+16 | 3.0E+16 | 4.0E+16 | 1.0E+17 |
| | Ave | 1.8E+16 | 3.0E+16 | 4.1E+16 | 9.8E+16 |
| [N] | 1 | 3.2E+15 | 4.6E+15 | 4.3E+15 | 4.5E+15 |
| | 2 | 3.1E+15 | 4.6E+15 | 4.5E+15 | 4.2E+15 |
| | 3 | 3.2E+15 | 4.4E+15 | 4.2E+15 | 4.2E+15 |
| | 4 | 2.9E+15 | 4.5E+15 | 4.1E+15 | 3.9E+15 |
| | Ave | 3.1E+15 | 4.5E+15 | 4.3E+15 | 4.2E+15 |
| No. 6 | | | | | |
| [Oi] | 1 | 5.3E+17 | 4.6E+17 | 4.1E+17 | 3.9E+17 |
| | 2 | 5.3E+17 | 4.1E+17 | 4.3E+17 | 3.6E+17 |
| | 3 | 5.7E+17 | 4.9E+17 | 4.1E+17 | 3.7E+17 |
| | 4 | 4.9E+17 | 4.3E+17 | 3.9E+17 | 3.6E+17 |
| | Ave | 5.3E+17 | 4.5E+17 | 4.1E+17 | 3.7E+17 |
| [C] | 1 | 2.1E+16 | 1.8E+16 | 4.0E+16 | 8.8E+16 |
| | 2 | 2.3E+16 | 1.9E+16 | 3.7E+16 | 8.2E+16 |
| | 3 | 2.0E+16 | 1.9E+16 | 3.9E+16 | 8.6E+16 |
| | 4 | 2.0E+16 | 2.0E+16 | 4.0E+16 | 9.0E+16 |
| | Ave | 2.1E+16 | 1.9E+16 | 3.9E+16 | 8.7E+16 |
| [N] | 1 | 3.1E+15 | 4.6E+15 | 4.1E+15 | 4.2E+15 |
| | 2 | 3.0E+15 | 4.4E+15 | 4.4E+15 | 3.9E+15 |
| | 3 | 3.2E+15 | 4.2E+15 | 4.1E+15 | 4.1E+15 |
| | 4 | 3.5E+15 | 4.4E+15 | 4.1E+15 | 4.2E+15 |
| | Ave | 3.2E+15 | 4.4E+15 | 4.2E+15 | 4.1E+15 |

Conditions 1a, 1b and 2 are defined as follows:

[Oi]≧2E17[atoms/cm³] (Condition 1a)

[Oi]+30×[N]≧2E17[atoms/cm³] (Condition 1b)

[C]≦1E17[atoms/cm³] (Condition 2)

It is apparent from Table 1 that, as far as Ingot is concerned, no substrate of any solidification rate satisfies the Conditions 1a, 1b or 2 at any of the four points of each substrate excluding 1 cm wide peripheral edge portions of substrate.

As for Ingot No. 2, substrate with solidification rate of 20% satisfies the Condition 1a and Condition 2 at all the four points of substrate excluding 1 cm wide peripheral edge portions of substrate. Substrate with solidification rate of 40% satisfies the Condition 1b and Condition 2 at all the four points of substrate excluding 1 cm wide peripheral edge portions of substrate. Substrates with solidification rates of 60% and 80% do not satisfy any of the Conditions 1a, 1b or 2 at any of the four points of substrate excluding 1 cm wide peripheral edge portions of substrate.

As for Ingot No. 3, substrate with solidification rate of 20% satisfies the Condition 1a and Condition 2 at all the four points of substrate excluding 1 cm wide peripheral edge portions of substrate. Substrates with solidification rates of 40% and 60% satisfy the Condition 1b and Condition 2 at all the four points of substrate excluding 1 cm wide peripheral edge portions of substrate. Substrate with solidification rate of 80% does not satisfy any of the Conditions 1a, 1b or 2 at any of the four points.

As for Ingot No. 4, substrate with solidification rate of 20% satisfies the Condition 1a and Condition 2 at all the four points of substrate excluding 1 cm wide peripheral edge portions of substrate. Substrates with solidification rates of 40% through 80% satisfy the Condition 1b and Condition 2 at all the four points of substrate excluding 1 cm wide peripheral edge portions of substrate.

As for Ingot No. 5, substrates with any solidification rate satisfies the Condition 1a and Condition 2 at all the four points of substrate excluding 1 cm wide peripheral edge portions of substrate.

As for Ingot No. 6, substrates with any solidification rate satisfies the Condition 1a and Condition 2 at all the four points of substrate excluding 1 cm wide peripheral edge portions of substrate.

From the discussion so far, the substrates that satisfy the Condition 1a and Condition 2 at all the four points excluding 1 cm wide peripheral edge portions of substrate (including substrate with solidification rate of 20% in Ingot No. 2, substrate with solidification rate of 20% in Ingot No. 3, substrate with solidification rate of 20% in Ingot No. 4, and all the substrates in Ingot No. 5 and Ingot No. 6) can be determined to be the substrates of the present invention.

Substrates that satisfy the foregoing Conditions 1a and 2, or Conditions 1b and 2 in at least a part of the foregoing areas can be also included in the substrates of the present invention, although there were no such specimens in this example. The reason that such substrates are in the scope of the present invention is that as far as an ingot is one that is produced by a usual casting method for which one-directional solidification is sufficiently ensured, distributions of [Oi] and [C] within the plane of a substrate that is cut out in a direction perpendicular to the ingot growth direction are almost homogeneous, and even when a variance occurs, it is within a range of several percent or so. Accordingly, as far as the foregoing Conditions 1a and 2 are satisfied in at least a part of the foregoing areas, it can be assumed that the Conditions 1a and 2 are also satisfied in other areas of the substrate.

Substrates that do not satisfy the foregoing conditions at any of the points of areas are substrates out of the scope of the present invention.

### <Cell Measurement>

Subsequently, solar cell elements were produced using substrates at positions of the respective solidification rates of Ingot Nos. 1-6.

The major conditions for solar cell element production were as follows:

The opposite conductivity-type region 4 was formed by thermal diffusion using POCl₃ as the diffusion source, targeting at achieving a sheet resistance of 65Ω/□. The surface collector electrodes 1 were formed by print and bake method using Ag paste composed mainly of silver. The baking here was carried out by RT process using an IR furnace, and a fire through method was used. The surface collector electrodes 1 were formed in a pattern including two bus bars 1a 2 mm in width arranged in parallel to the substrate edges across the length of 155 mm, and sixty three finger electrodes 1b of 100 μm in width arranged in parallel to the substrate edges across the length of 150 mm.

Average cell efficiency and crack/fracture percent defective of these solar cell elements were measured. Crack and fracture were checked by visual inspection and listening inspection (judging by vibration sound generated upon tapping on the substrate).

Table 3 shows the results of measurements performed on the foregoing Ingot No. 1 through Ingot No. 6 including average concentration of [Oi] measured at four points of a substrate excluding 1 cm wide peripheral edge portions of substrate, average concentration of [C] measured at the four points and average concentration of [N] measured at the four points, and average cell efficiency and crack/fracture percent defective of the produced solar cell elements.

TABLE 3

| | | | Upper [Oi] [atotms/cm³] | | | | | Crack |
|---|---|---|---|---|---|---|---|---|
| | | Quartz | Middle [C] [atoms/cm³] | | | | Average | fracture |
| | | powder | Lower [N] [atoms/cm³] | | | | cell | percent |
| Exp. | Casting | supply | Solidification rate | | | | efficiency | defective |
| No. | method | [g/min] | 20% | 40% | 60% | 80% | (%) | (%) |
| 1 | Conventional | 0.000 | 2.4E17 | 6.7E16 | 3.2E16 | 1.2E16 | 16.31 | 4.3 |
| | crucible | | 2.3E17 | 3.9E17 | 4.2E17 | 3.8E17 | | |
| | and | | 3.3E15 | 4.8E15 | 4.3E15 | 4.2E15 | | |
| | Conventional | | | | | | | |
| | mold | | | | | | | |
| 2 | Hermetically | 0.000 | 3.2E17* | 1.1E17** | 4.5E16 | 2.2E16 | 16.56 | 3.9 |
| | sealed | | 0.2E17* | 0.3E17** | 0.4E17 | 1E17 | | |
| | crucible and | | 3.4E15* | 4.6E15** | 4.2E15 | 4.1E15 | | |
| | Hermetically | | | | | | | |
| | sealed mold | | | | | | | |
| 3 | Hermetically | 0.002 | 3.6E17* | 1.5E17** | 9.2E16** | 6.4E16 | 16.57 | 3.6 |
| | sealed | | 0.2E17* | 0.3E17** | 0.5E17** | 1E17 | | |
| | crucible and | | 3.3E15* | 4.5E15** | 4.3E15** | 4.2E15 | | |
| | Hermetically | | | | | | | |
| | sealed mold | | | | | | | |
| 4 | Hermetically | 0.004 | 4.0E17* | 1.9E17** | 1.3E17** | 1.1E17** | 16.64 | 2.3 |
| | sealed | | 0.2E17* | 0.2E17** | 0.4E17** | 0.9E17** | | |
| | crucible and | | 3.3E15* | 4.4E15** | 4.2E15** | 4.1E15** | | |
| | Hermetically | | | | | | | |
| | sealed mold | | | | | | | |
| 5 | Hermetically | 0.008 | 4.6E17* | 2.8E17* | 2.3E17* | 2.1E17* | 16.67 | 1.7 |
| | sealed | | 0.2E17* | 0.3E17* | 0.4E17* | 1E17* | | |
| | crucible and | | 3.1E15* | 4.5E15* | 4.3E15* | 4.2E15* | | |
| | Hermetically | | | | | | | |
| | sealed mold | | | | | | | |
| 6 | Hermetically | 0.016 | 5.3E17* | 4.5E17* | 4.1E17* | 3.7E17* | 16.68 | 1.5 |
| | sealed | | 0.2E17* | 0.2E17* | 0.4E17* | 0.9E17* | | |
| | crucible and | | 3.2E15* | 4.4E15* | 4.2E15* | 4.1E15* | | |
| | Hermetically | | | | | | | |
| | sealed mold | | | | | | | |

*Within the scope of the invention (Conditions 1a, 2)
**Within the scope of the invention (Conditions 1b, 2)

It is apparent from Table 3 that carbon impurity concentration is remarkably reduced when the hermetically sealed crucible and hermetically sealed mold of the present invention are used.

In addition, crack/fracture percent defective is decreased and cell efficiency is improved when quartz power is supplied into the molten silicon to replenish oxygen. The reason for this is speculated that due to the increase of oxygen concentration in crystalline silicon, dislocation immobilization (because oxygen is segregated on the dislocation line by which dislocation fixation occurs) is promoted so that proliferation of dislocations is suppressed.

Additionally, in the CZ technique, it has been known that the dislocation fixation effect of nitrogen is about 30 times that of interstitial oxygen. The results of this example are in good agreement with this.

1. A polycrystalline silicon substrate for use in a photoelectric conversion element, comprising a region which contains concentrations of impurities that satisfy the following relations:
[Oi]>2E17 [atoms/cm³] (Condition 1a) and
[C]<E17 [atoms/cm³] (Condition 2)
where [Oi] is an interstitial oxygen concentration determined by Fourier transform infrared spectroscopy and [C] is a total carbon concentration determined by secondary ion mass spectrometry.

2. A polycrystalline silicon substrate according to claim 1, wherein the substrate is sliced out from an ingot.

3. A polycrystalline silicon substrate according to claim 2, wherein the substrate satisfies the Condition 1a and the Condition 2 at all regions excluding a 1 cm wide peripheral edge portion.

4. A polycrystalline silicon substrate for use in a photoelectric conversion element, comprising a region which contains concentrations of impurities that satisfy the following relations:
[Oi]+30×[N]≧2E17 [atoms/cm³] (Condition 1b) and
[C]≦1E17 [atoms/cm³] (Condition 2)
wherein [Oi] is an interstitial oxygen concentration determined by Fourier transform infrared spectroscopy, [N] is a total nitrogen concentration determined by second ion mass spectrometry, and [C] is a total carbon concentration determined by secondary ion mass spectrometry.

5. A polycrystalline silicon substrate according to claim 4, wherein the substrate is sliced out from an ingot.

6. A polycrystalline silicon substrate according to claim 5, wherein the substrate satisfies the Condition 1b and the Condition 2 at all regions excluding a 1 cm wide peripheral edge portion.

7. A polycrystalline silicon ingot for use in a photoelectric conversion element, comprising a region which contains concentrations of impurities that satisfy the following relations:
[Oi]≧2E17 [atoms/cm³] (Condition 1a) and
[C]≦E17 [atoms/cm³] (Condition 2)
where [Oi] is an interstitial oxygen concentration determined by Fourier transform infrared spectroscopy and [C] is a total carbon concentration determined by secondary ion mass spectrometry.

8. A polycrystalline silicon ingot for use in a photoelectric conversion element, comprising a region which contains concentrations of impurities that satisfy the following relations:
[Oi]+3×[N]≧2E17 [atoms/cm³] (Condition 1b) and
[C]≦1E17 [atoms/cm³] (Condition 2)
where [Oi] is an interstitial oxygen concentration determined by Fourier transform infrared spectroscopy, [N] is a total nitrogen concentration determined by secondary ion mass spectrometry, and [C] is a total carbon concentration determined by secondary ion mass spectrometry.

9. A method of producing a polycrystalline silicon substrate according to claim 1, comprising the steps of:
loading silicon into a crucible;
substantially hermetically sealing the crucible inside a heating furnace;
melting the silicon inside the crucible;
transferring molten silicon into a mold and solidifying and cooling the molten silicon while supplying oxygen to the molten silicon to obtain a polycrystalline silicon substrate.

10. A method of producing a polycrystalline silicon substrate according to claim 9, wherein the step of solidifying and cooling the molten silicon includes casting an ingot by solidifying and cooling the molten silicon inside the mold and slicing the casted ingot to obtain a polycrystalline silicon substrate.

11. A method of producing a polycrystalline silicon substrate according to claim 9, wherein the step of solidifying and cooling the silicon is carried out with the mold being substantially hermetically sealed.

12. A method of producing a polycrystalline silicon substrate according to claim 9, wherein quartz is loaded into the molten silicon for supplying oxygen to the molten silicon.

13. A method of producing a polycrystalline silicon substrate according to claim 1, comprising the steps of:
loading silicon inside the crucible;
melting the silicon inside the crucible;
transferring molten silicon into a mold;
substantially hermetically sealing the mold inside a heating furnace; and
solidifying and cooling the molten silicon while supplying oxygen to the molten silicon inside the mold to obtain a polycrystalline silicon substrate.

14. A method of producing a polycrystalline silicon substrate according to claim 13, wherein the step of solidifying and cooling the silicon includes casting an ingot by solidifying and cooling the molten silicon in the mold and slicing the casted ingot to obtain a polycrystalline silicon substrate.

15. A method of producing a polycrystalline silicon substrate according to claim 13, wherein quartz is loaded into the molten silicon for supplying oxygen to the molten silicon.

16. A method of producing a polycrystalline silicon substrate according to claim 1, comprising the steps of:
loading silicon into a mold;
substantially hermetically sealing the mold inside a heating furnace;
melting the silicon inside the mold; and
solidifying and cooling molten silicon while supplying oxygen to the molten silicon to obtain a polycrystalline silicon substrate.

17. A method of producing a polycrystalline silicon substrate according to claim 16, wherein the step of solidifying and cooling the molten silicon includes casting an ingot by solidifying and cooling the molten silicon in the mold and slicing the casted ingot to obtain a polycrystalline silicon substrate.

18. A method of producing a polycrystalline silicon substrate according to claim 16, wherein quartz is loaded into the molten silicon liquid for supplying oxygen to the molten silicon.

19. A photoelectric conversion element comprising a polycrystalline silicon substrate according to claim 1.

20. A photoelectric conversion module comprising a plurality of photoelectric conversion elements of claim 19 that are arranged in series or in parallel being electrically connected.
